(19) United States
(12) Patent Application Publication
(10) Pub. No.: US 2024/0064921 A1
(43) Pub. Date: Feb. 22, 2024

(54) SERVER HOST, SERVER DEVICE, AND SERVER SYSTEM

(71) Applicant: Wiwynn Corporation, New Taipei City (TW)

(72) Inventors: Chi-Lin Li, New Taipei City (TW); Wei-Hao Chen, New Taipei City (TW)

(21) Appl. No.: 17/951,187

(22) Filed: Sep. 23, 2022

(30) Foreign Application Priority Data
Aug. 17, 2022 (TW) 111131043

(51) Int. Cl. H05K 7/14

(52) U.S. Cl. CPC H05K 7/1487

(57) ABSTRACT

A server system includes a server host and a server device. The server host includes a first casing and an electrical substrate. The electrical substrate includes a first dock portion, a first metal shell, and a first magnetic piece. The first magnetic piece is in the first metal shell. The server device includes a second casing and a mainboard. The mainboard includes a second dock portion, a second metal shell, and a second magnetic piece. The second magnetic piece is in the second metal shell. The second dock portion is adapted to be docked with the first dock portion. A magnetic attraction force is generated between the first magnetic piece and the first magnetic piece, so that the second dock portion is docked with the first dock portion. Accordingly, the connection between the first dock portion and the second dock portion can be ensured.

### CROSS-REFERENCE TO RELATED APPLICATION

This non-provisional application claims priority under 35 U.S.C. § 119(a) to Patent Application No. 111131043 filed in Taiwan, R.O.C. on Aug. 17, 2022, the entire contents of which are hereby incorporated by reference.

### BACKGROUND

### Technical Field

The instant disclosure relates to a server system, particularly to a server system having a magnetic docking structure.

### Related Art

Servers are commonly utilized in our lives. A server and a host known to the inventor are connected to each other through blind-mating connection structures. The internal elastic piece(s) of the insertion structure clamps the plug or the receptacle so as to position the connection plug.

However, after the server and the host known to the inventor are connected to each other, during the transportation, the connection plug may have displacement. As a result, the connection plug may be detached from the host, or the components on the mainboard of the server may be impacted. Moreover, during the operation of the server and the host, if an external force is applied to the connection plug, the signal transmission between the server and the host may be unstable or even interrupted.

### SUMMARY

In view of this, the instant disclosure provides a server system. In one embodiment, the server system comprises a server host and a server device. The server host comprises a first casing and an electrical substrate. The electrical substrate is in the first casing, and the electrical substrate comprises a first dock portion, a first metal shell, and a first magnetic piece. The first magnetic piece is in the first metal shell. The server device comprises a second casing and a mainboard. The mainboard is in the second casing, and the mainboard comprises a second dock portion, a second metal shell, and a second magnetic piece. The second magnetic piece is in the second metal shell, and the second dock portion is adapted to be docked with the first dock portion. The second dock portion is at an insertion position, a magnetic attraction force is generated between the second magnetic piece and the first magnetic piece, so that the second dock portion is docked with the first dock portion.

According to some embodiments, the first metal shell has a first opening, and the second metal shell has a second opening. The first magnetic piece has a first magnetic-attracting surface exposed from the first opening, and the second magnetic piece has a second magnetic-attracting surface exposed from the second opening. When the first dock portion is docked with the second dock portion, the first magnetic-attracting surface contacts the second magnetic-attracting surface.

According to some embodiments, the first metal shell is connected to and surrounds the first dock portion, and the second metal shell is connected to and surrounds the second dock portion.

According to some embodiments, the first metal shell is at one side of the first dock portion, and the second metal shell is at one side of the second dock portion.

According to some embodiments, the first casing comprises a first sidewall and a first latch portion. The first sidewall has a guide portion and a position portion. The first latch portion is on the first sidewall. The second casing comprises a second sidewall and a bottom plate. The bottom plate is at one end of the second sidewall. The bottom plate has a second latch portion corresponding to the first latch portion, and the second latch portion is adapted to be locked with the first latch portion. The guide portion abuts against a surface of the second sidewall to limit the second sidewall to move along a first direction. The position portion is abutted against the stop portion to limit the second sidewall to move along a second direction.

The instant disclosure also provides a server host adapted to be electrically connected to a host device. In one embodiment, the server host comprises a first casing and an electrical substrate. The electrical substrate is in the first casing, the electrical substrate comprises a first dock portion, a first metal shell, and a first magnetic piece, and the first magnetic piece is in the first metal shell.

The instant disclosure further provides a server device adapted to be electrically connected to a server host. In one embodiment, the server device comprises a second casing and a mainboard. The mainboard is in the second casing, the mainboard comprises a second dock portion, a second metal shell, and a second magnetic piece, and the second magnetic piece is in the second metal shell.

According to some embodiments, the electrical substrate has the first magnetic piece, and the mainboard has the second magnetic piece. When the second dock portion of the main board is near the first dock portion of the electrical substrate, a magnetic attraction force is generated between the second magnetic piece and the first magnetic piece, so that the second dock portion is docked with the first dock portion. The magnetic attraction force allows the user to dock the second dock portion at the first dock portion quickly. Moreover, after the first dock portion is docked with the second dock portion, the docking between the first dock portion and the second dock portion can be ensured. Hence, according to some embodiments, the impacts on the server system caused by the external forces can be reduced. According to some embodiments, during the operation of the server device and the server host, the magnetic attraction force can further position the movements of the first dock portion and the second dock portion. Therefore, the risk of the signal transmission between the server device and the server host being unstable or even interrupted can be reduced.

According to some embodiments, through the arrangements of the first magnetic piece, the second magnetic piece, the guide portion, the position portion, the stop portion, the first latch portion, the second latch portion and the like, the tolerance chain between the server device and the server host can be reduced, thereby reducing the tolerance for locking and mating components of the server system. Therefore, the manufacturer can manufacture the server device and the server host conveniently, and the user can assemble/disassemble the server device with the server host.

### BRIEF DESCRIPTION OF THE DRAWINGS

The disclosure will become more fully understood from the detailed description given herein below for illustration only, and thus not limitative of the disclosure, wherein:

FIG. 1 illustrates a perspective view of a server system according to an exemplary embodiment;

FIG. 2 illustrates a perspective view of a first dock portion and a second dock portion of the server system according to an exemplary embodiment;

FIG. 3 illustrates a schematic view showing that the first dock portion and the second dock portion of the server system according to an exemplary embodiment are docked with each other;

FIG. 4 illustrates a cross-sectional view showing that the first dock portion and the second dock portion of the server system according to an exemplary embodiment are docked with each other;

FIG. 5 illustrates a perspective view of the first dock portion and the second dock portion of the server system according to an exemplary embodiment;

FIG. 6 illustrates a perspective view of the first dock portion and the second dock portion of the server system according to an exemplary embodiment;

FIG. 7 illustrates a perspective view of the first dock portion and the second dock portion of the server system according to an exemplary embodiment;

FIG. 8 illustrates a schematic view showing the operation of the embodiment shown in FIG. 7;

FIG. 9 illustrates an exploded partial view of a server host according to an exemplary embodiment; and

FIG. 10 illustrates an exploded partial view of a server device according to an exemplary embodiment.

### DETAILED DESCRIPTION

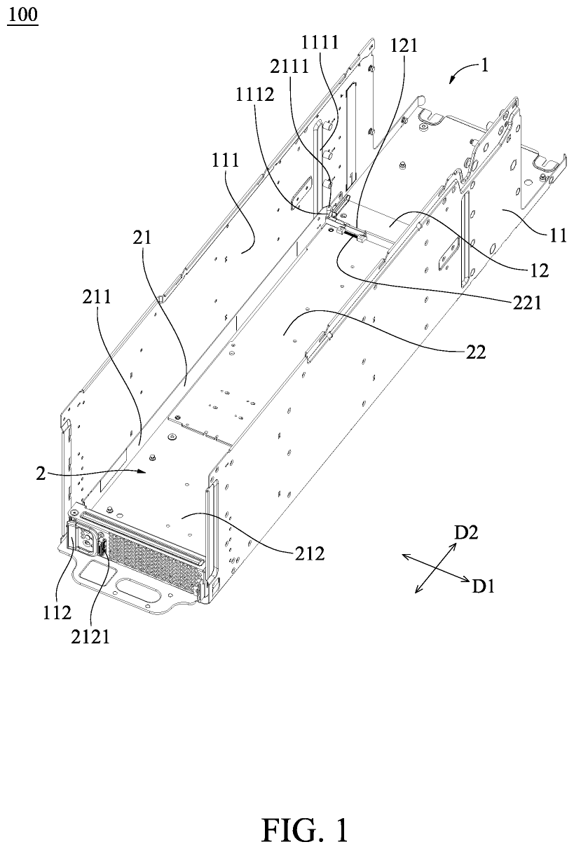

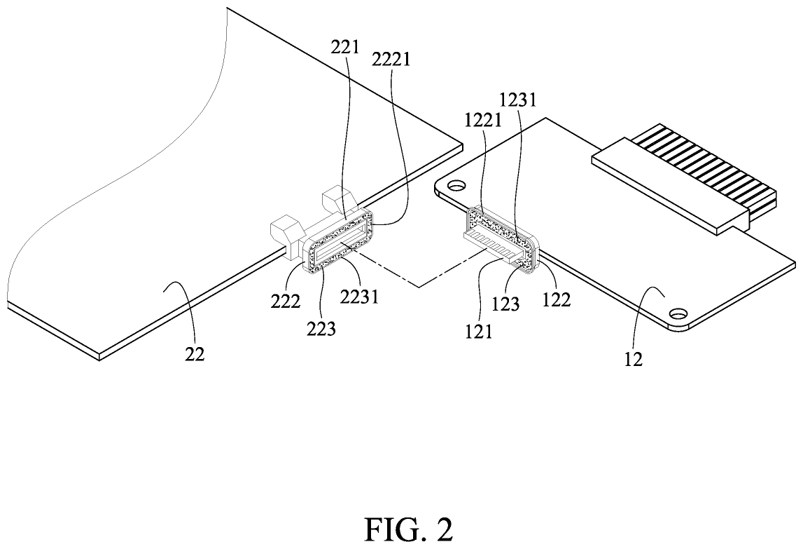

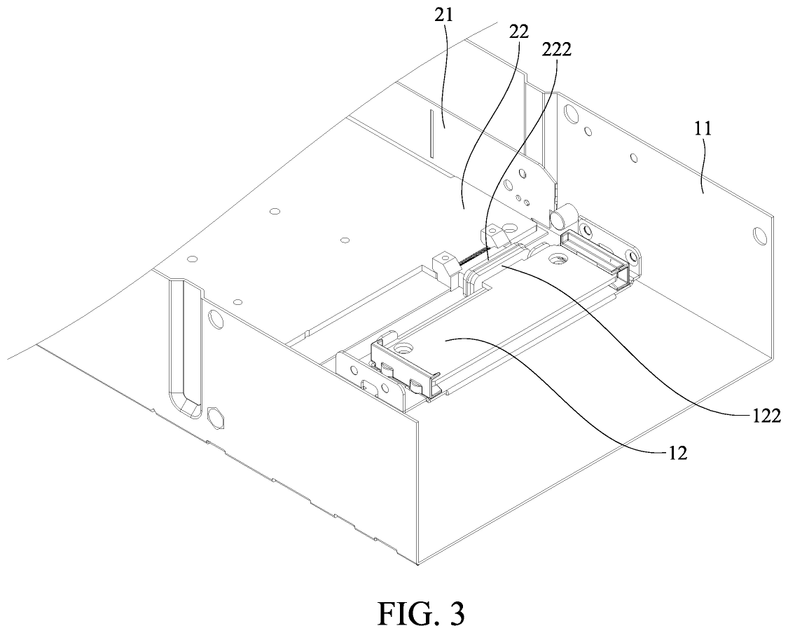

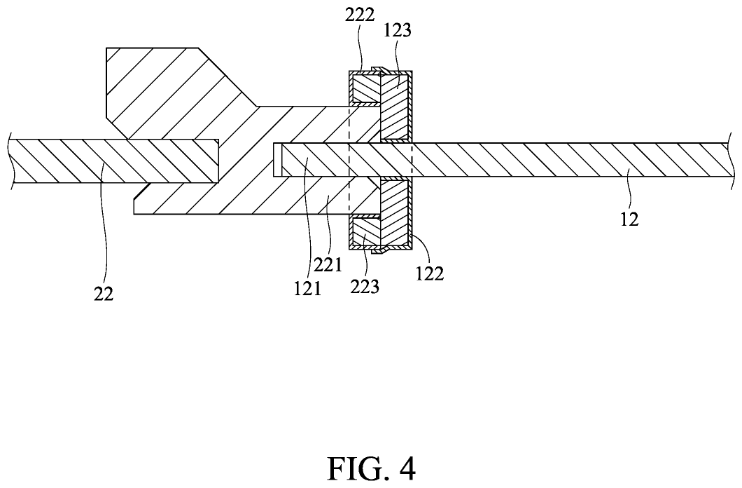

Please refer to FIG. 1 to FIG. 4. FIG. 1 illustrates a perspective view of a server system 100 according to an exemplary embodiment. FIG. 2 illustrates a perspective view of a first dock portion 121 and a second dock portion 221 of the server system 100 according to an exemplary embodiment. FIG. 3 illustrates a schematic view showing that the first dock portion 121 and the second dock portion 221 of the server system 100 according to an exemplary embodiment are docked with each other. FIG. 4 illustrates a cross-sectional view showing that the first dock portion 121 and the second dock portion 221 of the server system 100 according to an exemplary embodiment are docked with each other. The server system 100 comprises a server host 1 and a server device 2. For clearly showing the structure of an electrical substrate 12, a mainboard 22, the first dock portion 121, and the second dock portion 221 of the server system 100, in the embodiment shown in FIG. 1, internal components of the server host 1 and the server device 2 are omitted. The server host 1 comprises a first casing 11 and an electrical substrate 12. The electrical substrate 12 is in the first casing 11, and the electrical substrate 12 comprises a first dock portion 121, a first metal shell 122, and a first magnetic piece 123, and the first magnetic piece 123 is in the first metal shell 122. The server device 2 comprises a second casing 21 and a mainboard 22. The mainboard 22 is in the second casing 21, the mainboard 22 comprises a second dock portion 221, a second metal shell 222, and a second magnetic piece 223, and the second magnetic piece 223 is in the second metal shell 222. The second dock portion 221 is adapted to be docked with the first dock portion 121. The second dock portion 221 is at an insertion position, a magnetic attraction force is generated between the second magnetic piece 223 and the first magnetic piece 123, so that the second dock portion 221 is docked with the first dock portion 121.

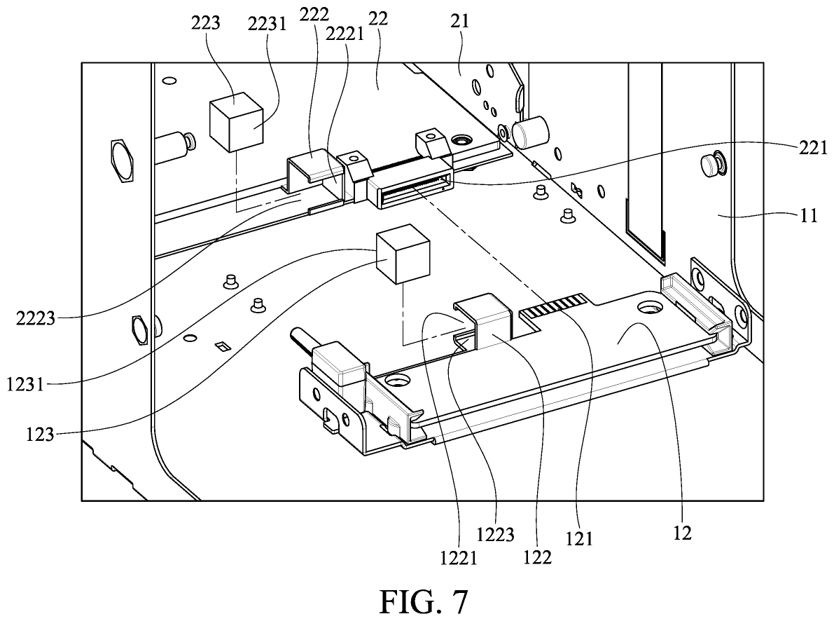

According to the embodiment shown in FIG. 2, the first dock portion 121 is a plug, such as a gold finger, and the second dock portion 221 is a receptacle, such as an insertion groove for the gold finger. However, the instant disclosure is not limited thereto; according to some embodiments, the first dock portion 121 is a receptacle, and the second dock portion 221 is a plug. According to some embodiments, the second dock portion 221 is a receptacle, and a metal elastic piece (not shown) is in the receptacle. The metal elastic piece can clamp the first dock portion 121 (the plug in these embodiment), so that the first dock portion 121 is positioned with the second dock portion 221. According to some embodiments, the first metal shell 122 and the second metal shell 222 are made of iron, the first metal shell 122 is soldered on the first dock portion 121, and the second metal shell 222 is soldered on the second dock portion 221, as shown in FIG. 2. According some other embodiments, the first metal shell 122 is soldered on the electrical substrate 12 and the second metal shell 222 is soldered on the mainboard 22, the first metal shell 122 is at one side of the first dock portion 121, and the second metal shell 222 is at one side of the second dock portion 221 (as shown in FIG. 7), which will be described later. The first magnetic piece 123 and the second magnetic piece 223 may be but not limited to magnets. The surface of the first magnetic piece 123 and the surface of the second magnetic piece 223 facing the surface of the first magnetic piece 123 are of different polarities. According to some embodiments, the server device 2 is a blade server; when the user is to connect the server device 2 with the server host 1, upon the server device 2 is near the server host 1 and the second dock portion 221 is at the insertion position, a magnetic attraction force is generated between the server device 2 and the server host 1. Therefore, the second dock portion 221 can be quickly and accurately docked with the first dock portion 121. The insertion position is a position where the distance between the first dock portion 121 and the second dock portion 221 is sufficient to allow the magnetic attraction force between the first magnetic piece 123 and the second magnetic piece 223 to be generated, and the insertion position is depended upon the volumes, the densities, and the magnetic conductivities of the first magnetic piece 123 and the second magnetic piece 223; the instant disclosure is not limited thereto. After the first dock portion 121 is docked with the second dock portion 221, the docking force between the first dock portion 121 and the second dock portion 221 can be enhanced by the magnetic attraction force, thereby ensuring the docking between the first dock portion 121 and the second dock portion 221. According to some embodiments, the first metal shell 122 is fixed on the electrical substrate 12 and the second metal shell 222 is fixed on the mainboard 22 by soldering. Therefore, the structures for docking the server host 1 and the server device 2 can be enhanced (in other words, in these embodiments, the first magnetic piece 123 is on the electrical substrate 12, and the second magnetic piece 223 is on the mainboard 22). According to some embodiments, the first metal shell 122 and the second metal shell 222 can be provided for shielding.

According to FIG. 2 and FIG. 4, the first metal shell 122 has a first opening 1221, and the second metal shell 222 has a second opening 2221. The first magnetic piece 123 has a first magnetic-attracting surface 1231 exposed from the first opening 1221, and the second magnetic piece 223 has a second magnetic-attracting surface 2231 exposed form the second opening 2221. When the first dock portion 121 is docked with the second dock portion 221, the first magnetic-attracting surface 1231 contacts the second magnetic-attracting surface 2231. According to some embodiments, the first metal shell 122 is on a portion of the first dock portion 121, and correspondingly the second metal shell 222 is on a portion of the second dock portion 221, but the instant disclosure is not limited thereto. According to the embodiment shown in FIG. 2 and FIG. 4, the first metal shell 122 is connected to and surrounds the first dock portion 121, and the second metal shell 222 is connected to and surrounds the second dock portion 221. As shown in FIG. 4, the first opening 1221 of the first metal shell 122 is greater than the second opening 2221 of the second metal shell 222, and a portion of the first metal shell 122 covers the second metal shell 222. However, the instant disclosure is not limited thereto. According to some embodiments, the first opening 1221 and the second opening 2221 have substantially the same size.

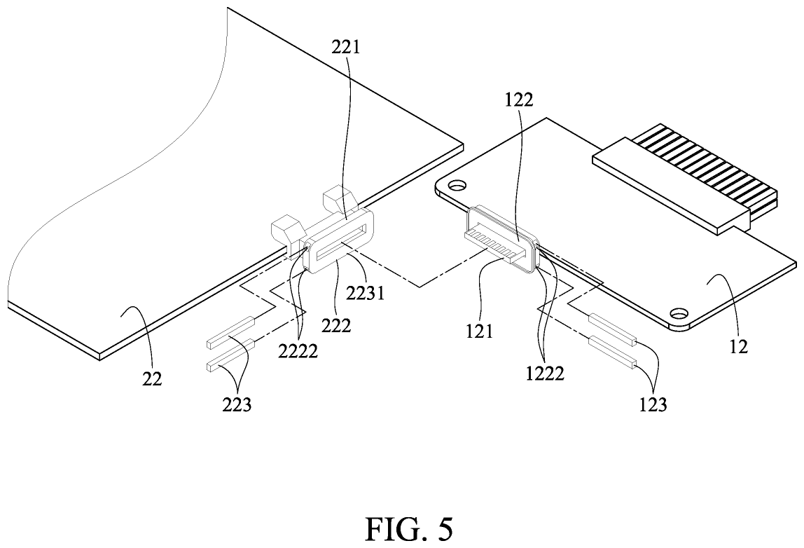

Please refer to FIG. 5. FIG. 5 illustrates a perspective view of the first dock portion 121 and the second dock portion 221 of the server system 10 according to an exemplary embodiment. According to the embodiment, the first metal shell 122 does not have the first opening 1221, and the second metal shell 222 does not have the second opening 2221. In this embodiment, the first magnetic piece 123 can be placed in a first receiving portion 1222 at a side surface of the first metal shell 122, and the second magnetic piece 223 can be placed in a second receiving portion 2222 at a side surface of the second metal shell 222. The first receiving portion 1222 of the first metal shell 122 and the second receiving portion 2222 of the second metal shell 222 can be sealed by PET films.

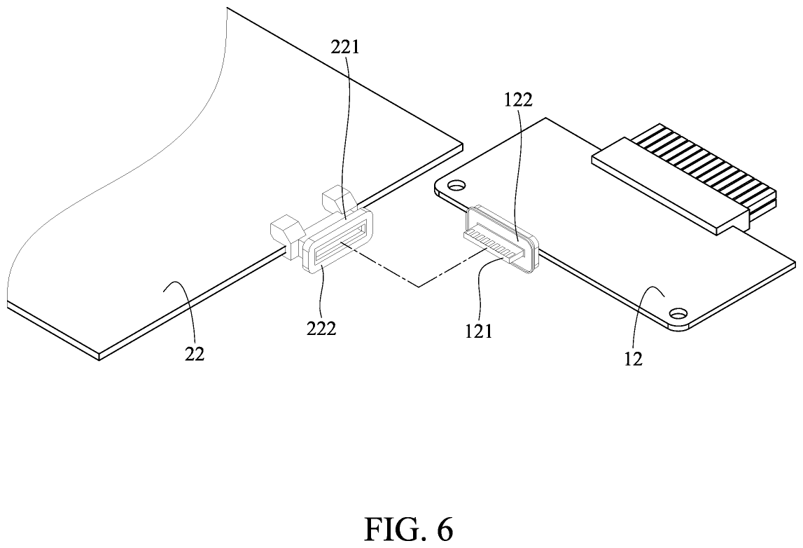

Please refer to FIG. 6. FIG. 6 illustrates a perspective view of the first dock portion 121 and the second dock portion 221 of the server system according to an exemplary embodiment. According to the embodiment, the first metal shell 122 encloses the first magnetic piece 123, and the second metal shell 222 encloses the second magnetic piece 223. In this embodiment, when the first dock portion 121 is docked with the second dock portion 221, the first magnetic-attracting surface 1231 does not contact the second magnetic-attracting surface 2231 directly; instead, the first metal shell 122 contact the second metal shell 222.

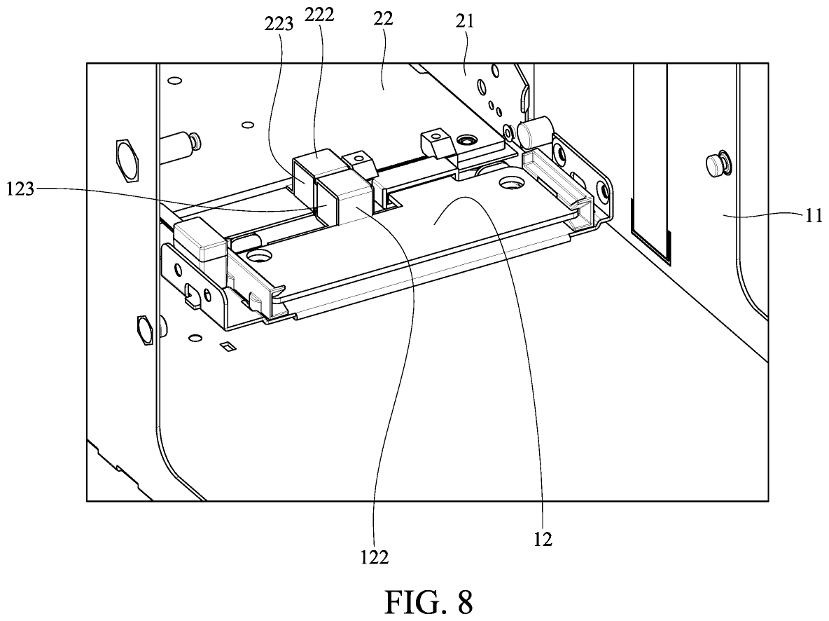

Please refer to FIG. 7 and FIG. 8. FIG. 7 illustrates a perspective view of the first dock portion 121 and the second dock portion 221 of the server system 10 according to an exemplary embodiment. FIG. 8 illustrates a schematic view showing the operation of the embodiment shown in FIG. 7. According to the embodiment, the first metal shell 122 is at one side of the first dock portion 121, and the second metal shell 222 is at one side of the second dock portion 221. As shown in FIG. 7, the first metal shell 122 is connected to the electrical substrate 12, and the second metal shell 222 is connected to the mainboard 22. According to some embodiments, the first metal shell 122 is connected to the electrical substrate 12 and the second metal shell 222 is connected to the mainboard 22 by soldering. The first metal shell 122 has a first opening 1221, and a side portion of the first metal shell 122 has a first hole 1223. The first magnetic piece 123 is placed in the first metal shell 122 from the first hole 1223, and the first magnetic-attracting surface 1231 is exposed from the first opening 1221. The second metal shell 222 has a second opening 2221, and a side portion of the second metal shell 222 has a second hole 2223. The second magnetic piece 223 is placed in the second metal shell 222 from the second hole 2223, and the second magnetic-attracting surface 2231 is exposed from the second opening 2221. When the second dock portion 221 is at the insertion position, a magnetic attraction force is generated between the first magnetic piece 123 and the second magnetic piece 223, so that the first dock portion 121 is docked with the second dock portion 221, and the first magnetic-attracting surface 1231 of the first magnetic piece 123 contacts the second magnetic-attracting surface 2231 of the second magnetic piece 223, as shown in FIG. 8. According to some embodiments, the first hole 1223 and the second hole 2223 can be sealed by PET films. According to some other embodiments, the first hole 1223 and the second hole 2223 may be sealed by metal plates. Hence, the first magnetic piece 123 and the second magnetic piece 223 can be positioned.

Please refer to FIG. 1 again. According to the embodiment, the first casing 11 comprises a first sidewall 111 and a first latch portion 112. The first sidewall 111 has a guide portion 1111 and a position portion 1112. The first latch portion 112 is on the first sidewall 111. The second casing 21 comprises a second sidewall 211 and a bottom plate 212. The second sidewall 211 has a stop portion 2111 at one end of the second sidewall 211, the bottom plate 212 has a second latch portion 2121 corresponding to the first latch portion 112, and the second latch portion 2121 is adapted to be locked with the first latch portion 112. The guide portion 1111 abuts against the surface of the second sidewall 211 to limit the second sidewall 211 to move along a first direction D1. The position portion 1112 is abutted against the stop portion 2221 to limit the second sidewall 211 to move along a second direction D2.

The guide portion 1111 can guide the user to place the server device 2 into the server host 1 and limit the server device 2 to move along the first direction D1. The position portion 1112 may be but not limited to a post, and the stop portion 2221 may be an extension plate of the second sidewall 211. The post may abut against the extension plate, so that the server device 2 is limited to move along the second direction D2. After the user assemble the server device 2 with the server host 1, the user can position the server host 1 and the server device 2 with each other by latching the first latch portion 112 and the second latch portion 2121 with each other. The latching between the first latch portion 112 and the second latch portion 2121 may be but not limited to engaging or buckling. In some embodiments, the first latch portion 112 and the second latch portion 2121 are locked with each other.

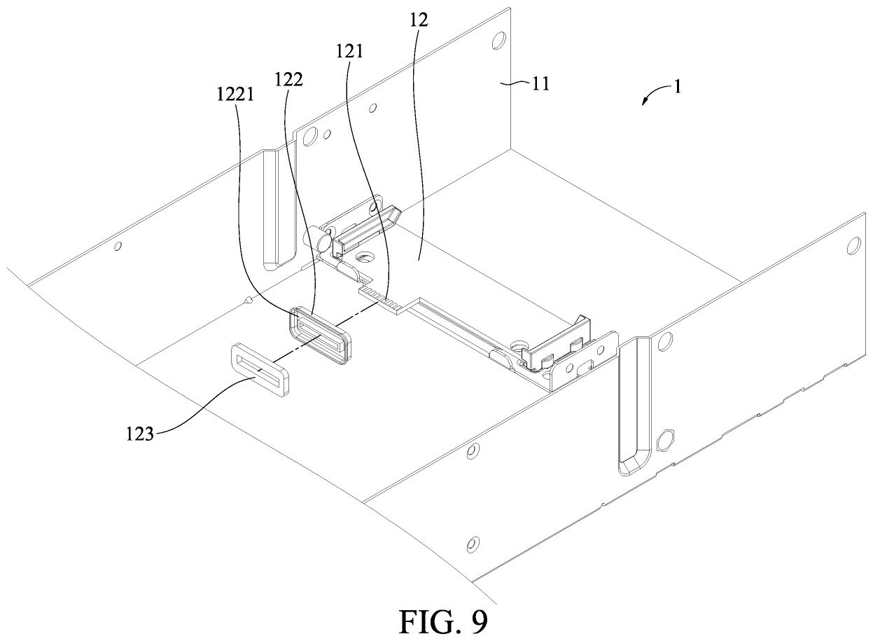

Please refer to FIG. 9. FIG. 9 illustrates an exploded partial view of a server host 1 according to an exemplary embodiment. The server host 1 is adapted to be electrically connected to the server device 2. The server host 1 comprises a first casing 11 and an electrical substrate 12. The electrical substrate 12 is in the first casing 11, the electrical substrate 12 comprises a first dock portion 121, a first metal shell 122, and a first magnetic piece 123, and the first magnetic piece 123 is in the first metal shell 122.

The first magnetic piece 123 may be a magnet. The first metal shell 122 may be but not limited to be made of iron. According to the embodiment, the first metal shell 122 is on the first dock portion 121, and the first magnetic piece 123 is in the first metal shell 122. According to some embodiments, the first magnetic piece 123 is at one side of the first dock portion 121 (as shown in FIG. 7). The first metal shell 122 can reinforce the insertion structure of the electrical substrate 12, such as the first magnetic piece 123 and the first dock portion 121. Moreover, the first metal shell 122 may be provided for shielding electrical fields.

According to some embodiments, the first metal shell 122 is on a portion of the first dock portion 121 (not shown). According to the embodiment shown in FIG. 9, the first metal shell 122 is connected to and surrounds the first dock portion 121, the first metal shell 122 has a first opening 1221, and a first magnetic-attracting surface 1231 of the first magnetic piece 123 is exposed from the first opening 1221. According to some other embodiments, the first metal shell 122 does not have the first opening 1221, and the first magnetic piece 123 is placed in the first metal shell 1222 from a first receiving portion 1222 at a side surface of the first metal shell 122 (as shown in FIG. 5). According to yet some other embodiments, the first metal shell 122 completely encloses the first magnetic piece 123 (as shown in FIG. 6).

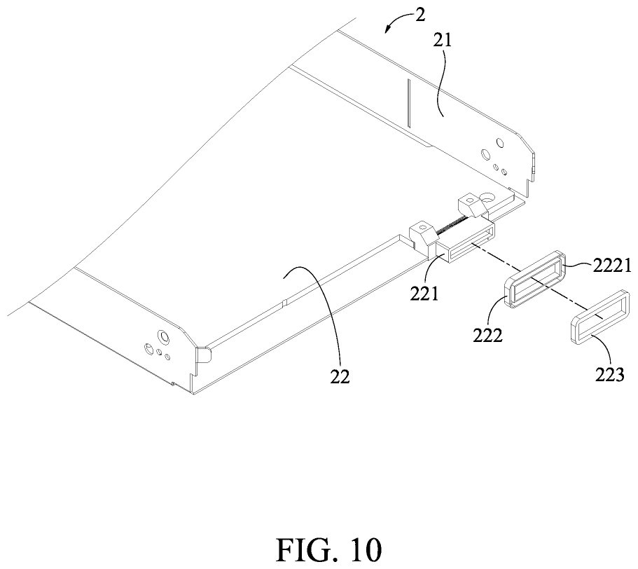

Please refer to FIG. 10. FIG. 10 illustrates an exploded partial view of a server device 2 according to an exemplary embodiment. The server device 2 is adapted to be electrically connected to a server host 1. The server device 2 comprises a second casing 21 and a mainboard 22. The mainboard 22 is in the second casing 21, the mainboard 22 comprises a second dock portion 221, a second metal shell 222, and a second magnetic piece 223, and the second magnetic piece 223 is in the second metal shell 222.

The second magnetic piece 223 may be a magnet. The second metal shell 222 may be but not limited to be made of iron. According to the embodiment, the second metal shell 222 is on the second dock portion 221, and the second magnetic piece 223 is in the second metal shell 222. According to some embodiments, the second magnetic piece 223 is at one side of the second dock portion 221 (as shown in FIG. 7). The second metal shell 222 can reinforce the insertion structure of the mainboard 22, such as the second magnetic piece 223 and the second dock portion 221. Moreover, the second metal shell 222 may be provided for shielding electrical fields.

According to some embodiments, the second metal shell 222 is on a portion of the second dock portion 221 (not shown). According to the embodiment shown in FIG. 10, the second metal shell 222 is connected to and surrounds the second dock portion 221, the second metal shell 222 has a second opening 2221, and a second magnetic-attracting surface 2231 of the second magnetic piece 223 is exposed from the second opening 2221. According to some other embodiments, the second metal shell 222 does not have the second opening 2221, and the second magnetic piece 223 is placed in the second metal shell 2222 from a second receiving portion 2222 at a side surface of the second metal shell 222 (as shown in FIG. 5). According to yet some other embodiments, the second metal shell 222 completely encloses the second magnetic piece 223 (as shown in FIG. 6).

According to some embodiments, the electrical substrate has the first magnetic piece, and the mainboard has the second magnetic piece. When the second dock portion of the main board is near the first dock portion of the electrical substrate, a magnetic attraction force is generated between the second magnetic piece and the first magnetic piece, so that the second dock portion is docked with the first dock portion. The magnetic attraction force allows the user to dock the second dock portion at the first dock portion quickly. Moreover, after the first dock portion is docked with the second dock portion, the docking between the first dock portion and the second dock portion can be ensured. Hence, according to some embodiments, the impacts on the server system caused by the external forces can be reduced. According to some embodiments, during the operation of the server device and the server host, the magnetic attraction force can further position the movements of the first dock portion and the second dock portion. Therefore, the risk of the signal transmission between the server device and the server host being unstable or even interrupted can be reduced.

The magnitude of the magnetic attraction force is depended upon the positions, the volumes, the densities, the magnetic conductivities, or the like of the first magnetic piece and the second magnetic piece, the instant disclosure is not limited thereto; the manufacturer can determine the magnitude based on the clients' needs.

According to some embodiments, through the arrangements of the first magnetic piece, the second magnetic piece, the guide portion, the position portion, the stop portion, the first latch portion, the second latch portion and the like, the tolerance chain between the server device and the server host can be reduced, thereby reducing the tolerance for locking and mating components of the server system. Therefore, the manufacturer can manufacture the server device and the server host conveniently, and the user can assemble/disassemble the server device with the server host.

What is claimed is:

1. A server system comprising:
a server host comprising:
a first casing; and
an electrical substrate in the first casing, wherein the electrical substrate comprises a first dock portion, a first metal shell, and a first magnetic piece, and the first magnetic piece is in the first metal shell; and
a server device comprising:
a second casing; and
a mainboard in the second casing, wherein the mainboard comprises a second dock portion, a second metal shell, and a second magnetic piece, the second magnetic piece is in the second metal shell, and the second dock portion is adapted to be docked with the first dock portion;
wherein the second dock portion is at an insertion position, a magnetic attraction force is generated between the second magnetic piece and the first magnetic piece, so that the second dock portion is docked with the first dock portion.

2. The server system according to claim 1, wherein the first metal shell has a first opening, and the second metal shell has a second opening; the first magnetic piece has a first magnetic-attracting surface exposed from the first opening, and the second magnetic piece has a second magnetic-attracting surface exposed from the second opening; when the first dock portion is docked with the second dock portion, the first magnetic-attracting surface contacts the second magnetic-attracting surface.

3. The server system according to claim 1, wherein the first metal shell is connected to and surrounds the first dock portion, and the second metal shell is connected to and surrounds the second dock portion.

4. The server system according to claim 1, wherein the first metal shell is at one side of the first dock portion, and the second metal shell is at one side of the second dock portion.

5. The server system according to claim 1, wherein the first casing comprises:
a first sidewall having a guide portion and a position portion; and
a first latch portion on the first sidewall;
the second casing comprises:
a second sidewall having a stop portion; and
a bottom plate at one end of the second sidewall, wherein the bottom plate has a second latch portion corresponding to the first latch portion, and the second latch portion is adapted to be locked with the first latch portion;
wherein the guide portion abuts against a surface of the second sidewall to limit the second sidewall to move along a first direction; the position portion is abutted against the stop portion to limit the second sidewall to move along a second direction.

6. The server system according to claim 1, wherein the first metal shell has a first opening, and the second metal shell has a second opening; the first magnetic piece has a first magnetic-attracting surface exposed from the first opening, and the second magnetic piece has a second magnetic-attracting surface exposed from the second opening; when the first dock portion is docked with the second dock portion, the first magnetic-attracting surface contacts the second magnetic-attracting surface;
wherein the first metal shell is connected to and surrounds the first dock portion, and the second metal shell is connected to and surrounds the second dock portion;
wherein the first casing comprises:
a first sidewall having a guide portion and a position portion; and
a first latch portion on the first sidewall;
the second casing comprises:
a second sidewall having a stop portion; and
a bottom plate at one end of the second sidewall, wherein the bottom plate has a second latch portion corresponding to the first latch portion, and the second latch portion is adapted to be locked with the first latch portion;
wherein the guide portion abuts against a surface of the second sidewall to limit the second sidewall to move along a first direction; the position portion is abutted against the stop portion to limit the second sidewall to move along a second direction.

7. A server host adapted to be electrically connected to a server device, wherein the server host comprises:
a first casing; and
an electrical substrate in the first casing, wherein the electrical substrate comprises a first dock portion, a first metal shell, and a first magnetic piece, and the first magnetic piece is in the first metal shell.

8. The server host according to claim 7, wherein the first metal shell has a first opening, and the first magnetic piece has a first magnetic-attracting surface exposed from the first opening.

9. The server host according to claim 7, wherein the first metal shell is connected to and surrounds the first dock portion.

10. The server host according to claim 7, wherein the first metal shell is at one side of the first dock portion.

11. The server host according to claim 7, wherein the first casing comprises first sidewall and a first latch portion, the first latch portion is on the first sidewall, and the first sidewall has a guide portion and a position portion.

12. The server host according to claim 7, wherein the first metal shell is connected to and surrounds the first dock portion;
wherein the first metal shell has a first opening, and the first magnetic piece has a first magnetic-attracting surface exposed from the first opening;
wherein the first casing comprises first sidewall and a first latch portion, the first latch portion is on the first sidewall, and the first sidewall has a guide portion and a position portion.

13. A server device adapted to be electrically connected to a server host, wherein the server device comprises:
a second casing; and
a mainboard in the second casing, wherein the mainboard comprises a second dock portion, a second metal shell, and a second magnetic piece, and the second magnetic piece is in the second metal shell.

14. The server device according to claim 13, wherein the second metal shell has a second opening, and the second magnetic piece has a second magnetic-attracting surface exposed from the second opening.

15. The server device according to claim 13, wherein the second metal shell is connected to and surrounds the second dock portion.

16. The server device according to claim 13, wherein the second metal shell is at one side of the second dock portion.

17. The server device according to claim 13, wherein the second casing comprises a second sidewall and a bottom plate, the bottom plate is at one end of the second sidewall, the second sidewall has a stop portion, and the bottom plate has a second latch portion.

18. The server device according to claim 13, wherein the second metal shell is connected to and surrounds the second dock portion;
wherein the second metal shell has a second opening, and the second magnetic piece has a second magnetic-attracting surface exposed from the second opening;
wherein the second casing comprises a second sidewall and a bottom plate, the bottom plate is at one end of the second sidewall, the second sidewall has a stop portion, and the bottom plate has a second latch portion.
